(19) United States
(12) Patent Application Publication
(10) Pub. No.: US 2007/0096956 A1
(43) Pub. Date: May 3, 2007

(54) STATIC DEFINED WORD COMPRESSOR FOR EMBEDDED APPLICATIONS

(75) Inventor: Paul Henry Chandler Smith, Salt Lake City, UT (US)

Correspondence Address: Powell and Associates, P.O. Box 1679, American Fork, UT, 84003, US

(73) Assignee: FUJIFILM Microdisks USA Inc.

(21) Appl. No.: 11/263,610

(22) Filed: Oct. 31, 2005

(51) Int. Cl. H03M 7/34

(52) U.S. Cl. 341/51

(57) ABSTRACT

The present invention provides lossless, static defined-word compression without a tree structure or recursion, thereby reducing the use of processing resources and memory. The efficiency of the present invention does not decrease when the message probability distribution is highly skewed, and the present invention does not limit the length of codewords. Pursuant to the teachings of the present invention compression efficiency can reach within 1% of the theoretical minimum entropy. The present invention also naturally provides decompression without storing codewords in the translation table, providing a more compact translation table.

### BACKGROUND OF THE INVENTION

The invention relates to the field of data compression, and in particular to a data compression method ideally suited for embedded applications.

Static defined-word compressors, particularly Huffman compressors and Shannon-Fano compressors, are used for lossless compression of data in many data storage and transmission applications, including most audio, video, and image codecs. Increasingly this type of data is being processed by embedded applications like those found in most portable devices. Digital cameras and camcorders are decreasing in size and are being combined with mobile telephones or PDA's. Portable media players that store, process, and play audio and video data are also becoming extremely common. As these and other devices become smaller, it is important that each of the data processing algorithms, including the data compression algorithm, are optimized to use the minimum amount of memory and processing resources possible to allow for smaller sizes and to keep the device cost to a minimum. Data storage drives for these devices and for traditional computers are also growing in storage size, and need simpler more efficient compression algorithms to process such large amounts of data.

Data compression is viewed theoretically as a communication channel where a source ensemble containing messages in alphabet a is mapped to a set of codewords in alphabet b. In other words, a set of data that is represented by messages (each containing one or more symbols) that are not an optimal length are assigned codewords of an optimal length in order to shorten the ensemble.

Static defined-word compressors like Huffman or Shannon-Fano compressors are entropy encoders. Information entropy differs from entropy in the thermodynamic sense. Information theory defines entropy as the information content of a message. It dictates that messages that occur most often are more predictable and therefore contain less information. Those messages that occur less often are less predictable and contain more information. This definition of entropy is the basis upon which entropy encoders, such as Huffman and Shannon-Fano, operate. Under entropy encoding rules, when mapping codewords from alphabet a to codewords in alphabet b, the codewords that are used most often from alphabet a are assigned to the shortest codewords in alphabet b. Pursuant to the definition of entropy these high frequency codewords from alphabet a contain less information, and will therefore be assigned shorter codewords from alphabet b. Less frequently occurring code words from alphabet a are assigned to longer codewords in alphabet b because the less frequently occurring code words contain far more information.

### SUMMARY OF THE INVENTION

The present invention provides lossless, static defined-word compression without a tree structure or recursion, thereby reducing the use of processing resources and memory. The efficiency of the present invention does not decrease when the message probability distribution is highly skewed, and the present invention does not limit the length of codewords. Pursuant to the teachings of the present invention compression efficiency can reach within 1% of the theoretical minimum entropy. The present invention also naturally provides decompression without storing codewords in the translation table, providing a more compact translation table.

### BRIEF DESCRIPTION OF THE DRAWINGS

FIG. 1 is a table showing the steps of Huffman compression using a binary tree.

FIG. 2 is a table showing the recursive steps of Shanon-Fano compression.

FIG. 3 is a table showing a first embodiment of the present invention.

FIG. 4 is a table showing a second embodiment of the present invention.

FIG. 5 is a table showing a third embodiment of the present invention.

FIG. 6 is a table showing a fourth embodiment of the present invention.

FIG. 7 is a table showing a fifth embodiment of the present invention using fixed point arithmetic.

FIG. 8 is a table showing a sixth embodiment of the present invention.

### DETAILED DESCRIPTION OF THE INVENTION

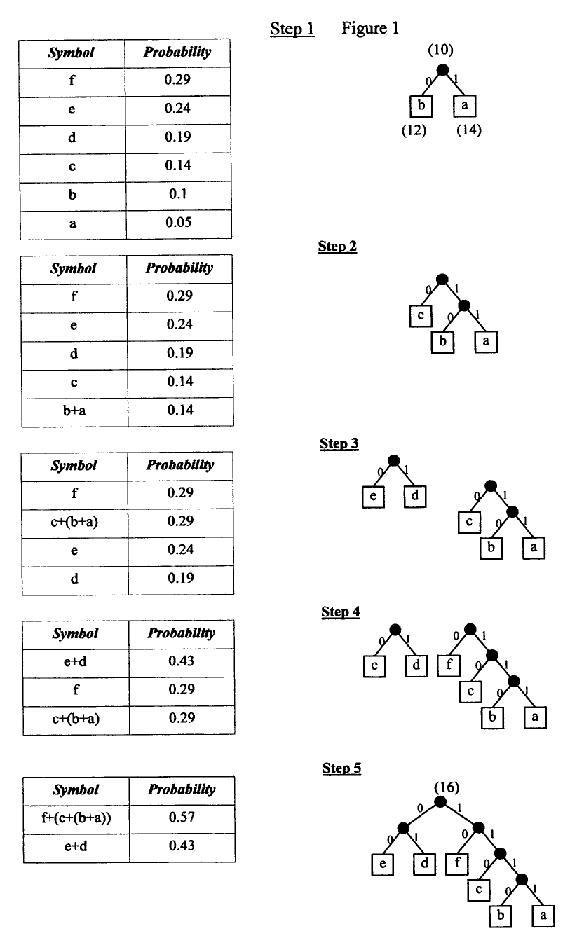

As illustrated by FIG. 1, Huffman compressors assign codewords to each message in alphabet a by building a binary tree using a weight for each message. While the weights assigned to each message are typically the probabilities that the message will occur in the ensemble, like in FIG. 1, this is not necessarily the case. Weights may also be counts, frequencies, or another metric. All message are listed in order of decreasing weights. A binary tree (10) is then constructed, starting with the two messages in the list that have the lowest weights (12,14), as seen in FIG. 1, step 1. The message with the highest weight (12) is placed on the left. After being placed in the binary tree, the weights of the two messages (12,14) are combined and they are viewed as a single node or message with the combined weight of the two original messages. The two messages are then removed from the list and the new node is added with the new weight. This is the node (b+a) in step 2 of FIG. 1. The process is then repeated using the next two nodes with the lowest weight in the new list. It continues until the list contains only a single entry. In FIG. 1 this happens when the two nodes in step 5 are added to the binary tree and combined. Typically the codewords are determined by labeling branches such that branches on the right are 1 and branches on the left are 0. The tree is then traversed in order to determine the codeword for each message. For instance, the code word for “a” is found by tracking from node to node from root node 16 along the branches until reaching node “a”. Thus the codeword for “a” yields “1111” as shown in the table of FIG. 9. Similarly, tracking along the branches from node 16 to node “e” yields “00”.

Huffman compressors require a significant amount of memory to store each node of the binary tree, and have a code space that also requires a large amount of memory. Memory use is a critical consideration for embedded applications which needs to conserve memory. Most implementations of Huffman decompression also involves either traversing a tree structure or scanning a list of codewords, which requires both time and memory. The compression efficiency of the Huffman algorithm also decreases when the distribution of weights or probabilities is heavily skewed. This occurs when a small number of messages, typically one or two, occur much more often than the rest of the messages in the alphabet.

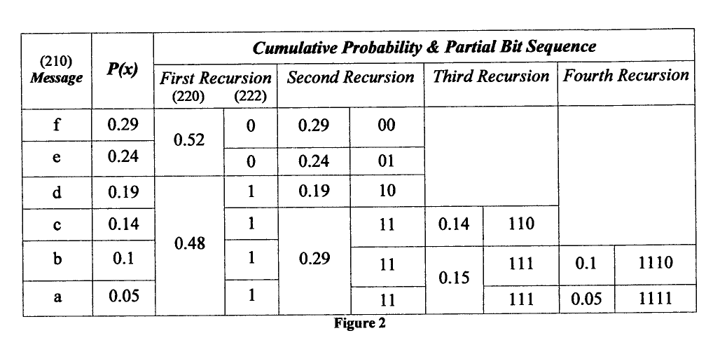

Shannon-Fano compressors also assign minimum prefix codewords based on the probability that a message will occur. The table in FIG. 2 illustrates how this is accomplished. The messages are first ordered based on the decreasing probability that they will occur. This is the message column 210 in FIG. 2. The list is then divided at the point where each sublist contains as close as possible to 50% of the total probability of all items in the list (see column 220). A zero is then appended to each codeword in the top sublist, and a one is appended to each codeword in the bottom sublist (see column 222). This process is repeated recursively on each sublist until each message has a unique codeword, as the second, third, and fourth recursions in FIG. 2 illustrate.

The recursion used by the Shannon-Fano compressor is not practical on systems with very limited memory for stack space. Even if recursion is not actually used, additional memory is required to effectively emulate recursion. Significant memory is also needed during the traversal of the list of messages to keep track of relevant data. A list of codewords is also necessary for decompression, increasing the size of the translation table (also called a codebook) and the memory necessary for decompression.

While other static defined-word compressors exist, most are more complicated variations of the Huffman or Shannon-Fano methods. Other methods require multiple passes through the list of messages in order to properly assign the unique codewords. Many of the compressors also have limits on codeword length, which can both restrict and complicate the compressor's use. The compression efficiency of these compressors is generally lower than that of the Huffman compressor.

The present invention provides lossless, static defined-word compression without a tree structure or recursion, making only one pass through the list of messages. Thus the present invention reduces use of processing resources and memory. The efficiency of the present invention does not decrease when the message probability distribution is highly skewed, and the present invention does not limit the length of codewords. Pursuant to the teachings of the present invention compression efficiency can reach within 1% of the theoretical minimum entropy. The present invention also naturally provides decompression without storing codewords in the translation table, providing a more compact translation table.

The present invention assigns numerically ordered codewords that represent the cumulative probability of the processed messages. This comprises the steps of:

a ordering the messages based on decreasing probability of occurrence;

b. defining a running codeword;

c. assigning the codeword to the first message whose probability is within a predefined set of bounds;

d. incrementing the codeword;

e. assigning the codeword to the next message whose probability is within the set of bounds;

f. repeating the previous steps until every message whose probability is within the set of bounds has been assigned a codeword;

g. left shift the codeword by one bit; and

h. repeating the entire process for each additional set of bounds until every message has been assigned a codeword.

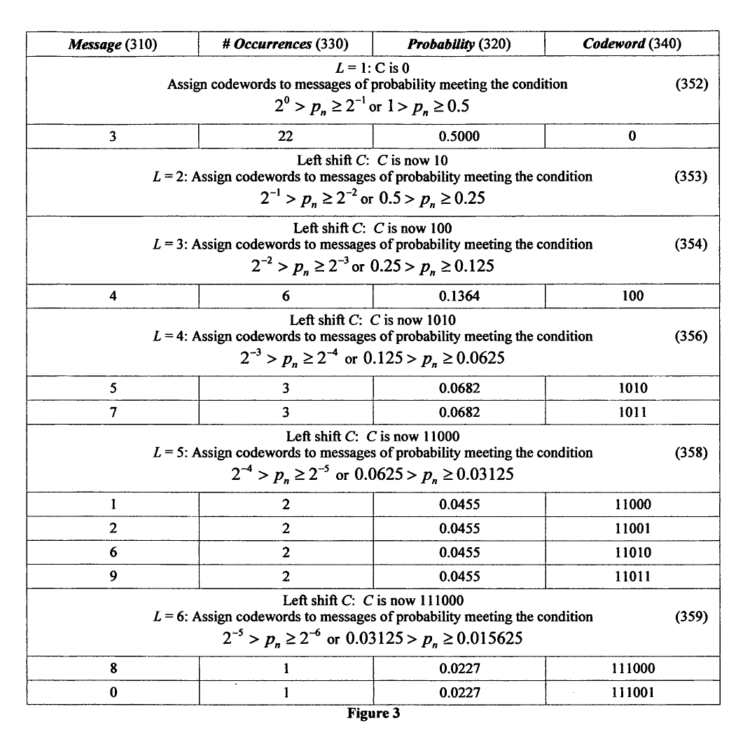

The table in FIG. 3 outlines this basic compression process in a first embodiment of the present invention using the example ensemble:

53433438353533373936239324343433437317331063

For any message (column 310) in the ensemble, a probability pₙ is assigned based on the number of times that the message occurs in ensemble s such that:

$${\sum }_{n = 0}^{N - 1} {p}_{n} = 1$$

The number of occurrences and the associated probabilities are listed in the second (column 320) and third (column 330) columns respectively in FIG. 3. Note that while probabilities are used here, counts, frequencies, or other metrics may also be used. After probabilities, or weights, have been assigned, the messages 310 are ordered based on decreasing probability of occurrence (note the messages 310 listed according to decreasing numbers of occurrence as shown in column 320).

A running codeword C (“running” meaning that C will change and increment) is then defined. In the first embodiment, codeword C is initially set to 0 with codeword length L=1. As illustrated in FIG. 3 the list of messages is separated into groups by a predetermined set of bounds. In FIG. 3 the bounds are set based on codeword length L from the equation:
2^{-L+1}>pₙ≧2^{-L}

By using these bounds, the codewords assigned will represent the fractional cumulative probability of the messages that have been assigned codewords within each respective predetermined set of bounds.

The running codeword C is then assigned to the first message on the list within the set of bounds. In FIG. 3 the first bound (352) is assigned C=0 with L=1. The message from the example ensemble that has a probability falling within the range defined for bound 352 (note equation) is message “3” having occurrences of 22 and a probability of 0.5000 which is the lower range for bound 352. Since running codeword C was assigned 0 for the first message in this bound, the codeword for message “3” is “0” (see column 340). C is then incremented by 1 and the process is repeated until all messages within the prescribed set of bounds have been assigned codewords. Therefore, if another message had a probability that fell within the range defined in bound 352 that next message would be assigned codeword C=1 (incremented by 1 from C=0). In FIG. 3 the only message that falls within the first set of bounds is 3.

The length L is then incremented by 1, and the running codeword C is left shifted by 1 to generate the second bound, bound 353 having codeword length 2. Note that the last available codeword from bound 352 is C=1 (C=0 used for message “3”). By left shifting, the first available codeword to bound 353 is C=10. Referring back to the example ensemble, there are no messages having a probability that fit within the range defined for bound 353. Accordingly, no message is assigned to bound 353. This means that the last available codeword for bound 353 is C=10.

Length L is again incremented by 1 (L=3) and the running codeword C is left shifted again by 1 to generate the second bound, bound 354 having codeword length 3. For bound 354 message “4” has a probability that fits within the specified range (occurrence of 6 and probability of occurrence of 0.1364). By left shifting the previously available codeword from bound 353 (10), the resultant codeword available for the first potential message is “100”. Message 4 is then assigned C=100. Note here that the next available codeword for bound 354 is C=101 (100 incremented by 1). There are no other messages from the example ensemble that fit within the predefined range for bound 354. Therefore, the last available codeword for bound 354 is 101.

Referring now to bound 356, L is now 4 and the initial codeword available is C=1010 since the last available codeword from bound 354 was 101. Left shifting 101 yields C=1010. Note the two messages falling within the predefined range for bound 356 are 5 and 7 having codewords 1010 and 1011 (incrementing C by 1) respectively.

The above process is repeated for bound 358. Here note that L is incremented by 1 and the last available codeword from bound 356 is left shifted to yield the first available codeword in bound 358 of C=l 1000. In bound 358 there are four messages that have probabilities that fall within the defined range (1, 2, 6, and 9). Note that codeword C is incremented by 1 each time yielding C1=11000, C2=11001, C6=11010, and C9=11011. The next available codeword, incrementing by 1, would be C=11100. Since there are no other messages falling within bound 358, this codeword remains the last available codeword for bound 358.

Finally, bound 359 is defined in the same manner, incrementing L by 1 and left shifting the last available codeword from bound 358. There are two messages from the example ensemble that fall within this range. They are 8 and 0 and are assigned codewords 111000 and 111001 respectively, according to the procedure defined above.

This first embodiment of the present invention has a worst case efficiency comparable to a Shannon-Fano compressor. For any message mₙ with probability of occurrence pₙ the present invention will produce a codeword of length

This means that:

$${L}_{n} = ⌈ - {log}_{2} ( {p}_{n} ) ⌉$$

$$⌈ - {log}_{2} ( {p}_{n} ) ⌉ + {log}_{2} ( {p}_{n} ) < 1$$

Therefore, the maximum entropy (in bits) in the compressed ensemble will always be less than:

$$H < 1 + {\sum }_{n ∈ a} ( - {p}_{n} {log}_{2} ( {p}_{n} ) )$$

This is identical to the maximum entropy obtained with a Shannon-Fano compressor.

The theoretical minimum length that the example ensemble in FIG. 3 could be compressed to would be 109.1 bits. In practice it has been found that the basic compression algorithm of the first embodiment of the present invention produces a sequence of length 116 bits. The theoretical maximum for a Shannon-Fano compressor (and this compressor) is 153.09 bits. For a Huffman compressor the theoretical maximum is roughly 135 bits. For the example ensemble used for FIG. 3, the Shannon-Fano compressor yields a compressed sequence 111 bits in length. The Huffman compressor yields a compressed sequence of 113 bits in length. Obviously the present invention yields a compression sequence requiring less memory than that of Shannon-Fano and Huffman compressors.

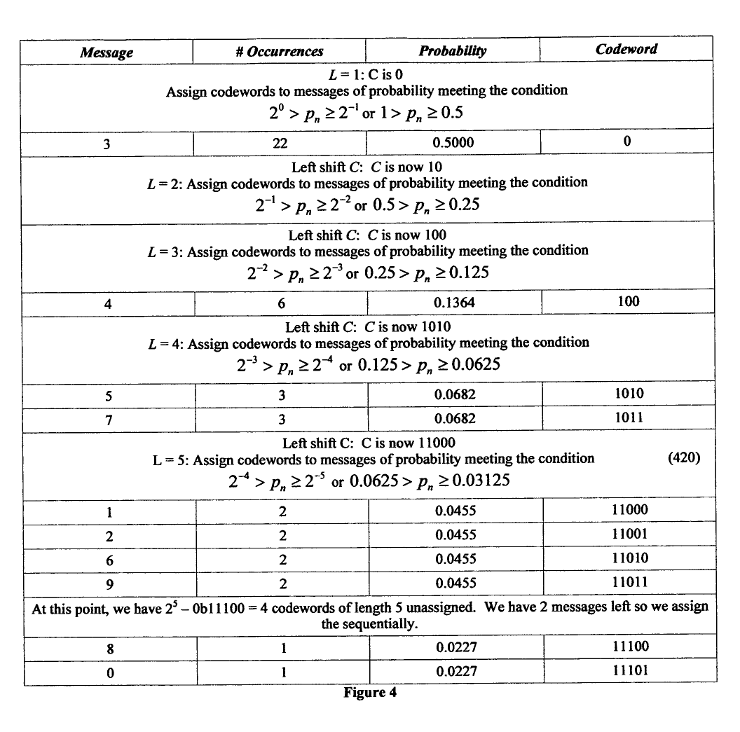

FIG. 4 shows a second embodiment of the present invention which is an improvement on the first embodiment of the present invention. Before running codeword C is incremented between sets of bounds, the number of remaining messages that need codewords is compared to the number of available codewords of the current length. When the number of remaining messages is less than or equal to the number of available codewords, the compressor maps all remaining messages to the available codewords sequentially instead of increasing the codeword length. In FIG. 4, note that four messages fell within the defined range of bound 420 which is the same as bound 358 in FIG. 3. Those messages include 1, 2, 6, and 9. There remain within bound 420 4 unused codewords, each of length 5 which include 11100, 11101, 11110, and 11111. Under the analysis of the second embodiment, messages 8 and 0 which would have been assigned to the next bound (359 in FIG. 3) are assigned, within bound 420, codewords of length L=5 instead of L=6. This is possible because only two messages remain to be included whereas there are 4 available codewords remaining. This reduces the length of the compressed ensemble by 2 bits without any extra passes through the list.

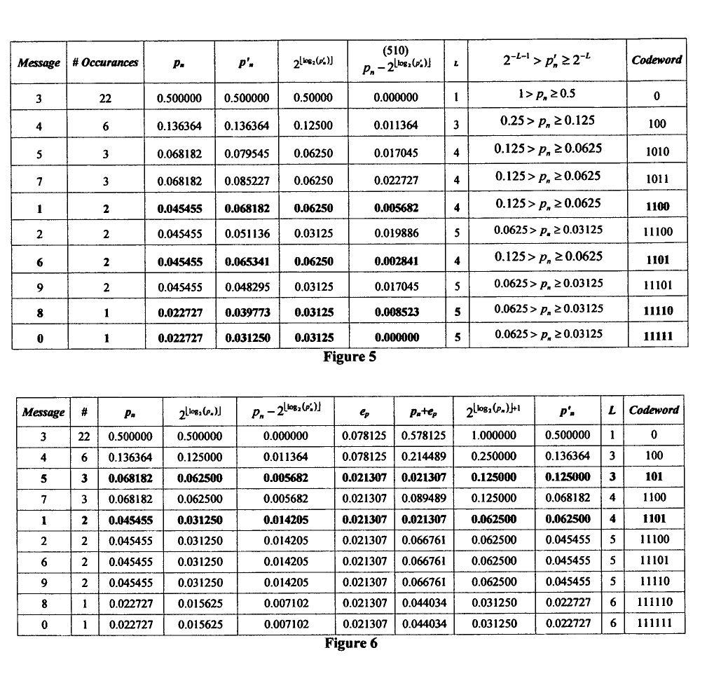

Each codeword assigned by the first embodiment is in fact a representation of the cumulative probabilities of all messages in the list that have already been processed, but truncated to L bits. The codewords can be viewed as a binary fractional number with a decimal point before the first digit of the codeword. FIG. 5 shows a third embodiment of the basic algorithm of the present invention that improves the efficiency of the compressor by recognizing this fact. A rounding error is introduced by the truncation that can be taken into account to optimize the compression. In this third embodiment, an initial pass by the compressor adds the rounding error in column 510 (introduced by the codeword that was assigned to the previous message) to the probability of the current message to provide codeword lengths that are more optimal. In this embodiment, the following equation is used to calculate the new probabilities, where p′ₙ is the new probability, pₙ is the original probability, and p′ₙ₋is the new probability that was assigned to the previous message.
p′ₙ=pₙ+(p′ₙ₋−2^{└log}^{₂}^{(p′}^{_{n−1}}^{)┘})

After the new altered weights or probabilities have been assigned, the original basic compressor of the first embodiment is used, substituting p′ₙ for pₙ. In FIG. 5 messages 1, 6, 8, and 0 are each assigned codewords with lengths which are 1 bit shorter than those assigned by the first embodiment. This makes the compressed sequence produced in FIG. 5 exactly 110 bits long, which is the theoretical limit.

The third embodiment illustrated in FIG. 5 is more likely to decrease the length of codewords that are assigned to messages with lower probabilities, which therefore appear less in the original message. FIG. 6 shows a fourth embodiment that optimizes the codewords assigned to higher probability messages first. To do this a truncation error term, eₚ is first calculated using:

$${e}_{p} = \{ {\sum }_{m ∈ a} ⌊ {p}_{m} - {2}^{⌊ {log}_{2} ( {p}_{m} ) ⌋} ⌋ \} - {2}^{⌊ {log}_{2} ( {p}_{N - 1} ) ⌋}$$

The term P_{N-1} is the probability of the message with the lowest probability of occurrence in a. The first message mₙ in the list is then tested by the rule:
pₙ+eₚ≧2^{└log}^{₂}^{(p}^{ₙ}^{)┘+1}

If the condition is true, then a new p′ₙ is calculated using the equation:
p′ₙ=2^{└log}^{₂}^{(p}^{ₙ}^{)┘+1}

After p′ₙ is calculated eₚ is also decreased by the following amount to reflect the correction that has been made to the truncation error:
2^{└log}^{₂}^{(p}^{ₙ}^{)┘+1}−pₙ

If the above rule was false, no changes are made to eₚ, and p′ₙ is given the original value of pₙ. The process is then repeated for each message in the list, and codewords are then calculated using the basic algorithm of the first embodiment, again substituting p′ₙ for pₙ. FIG. 6 shows that using this fourth embodiment compressor on the example message decreases the length of codeword for message 5 and 1 instead of messages 1, 6, 8, or 0. Messages 5 and 1 occur more often than 6, 8, or 0.

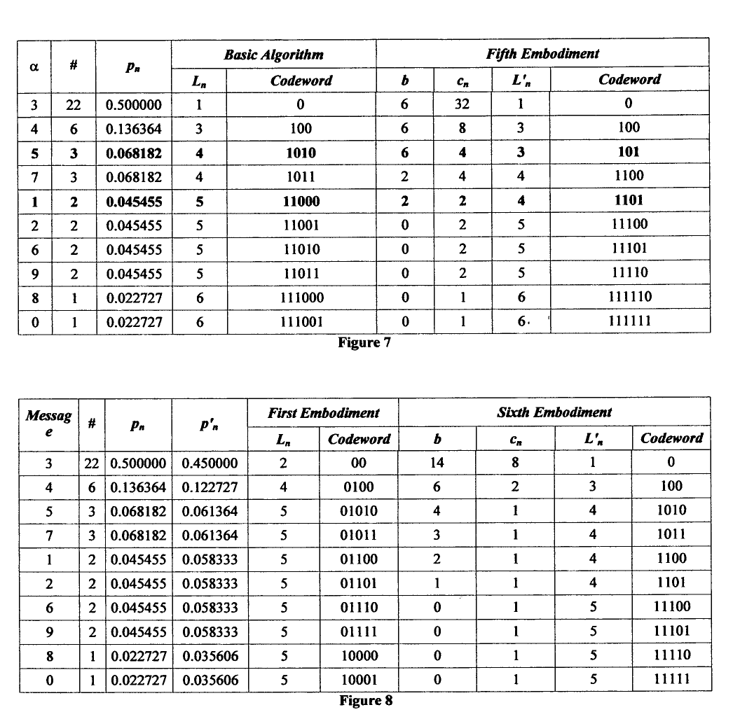

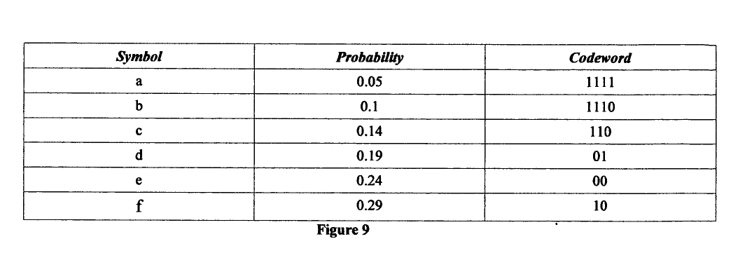

For embedded systems that are limited to fixed point arithmetic, alterations can be made to simplify the fourth embodiment of the present invention outlined above. One such alteration is outlined in FIG. 7 as the fifth embodiment.

The basic algorithm of the first embodiment of the present invention is first applied to the list of message probabilities to determine the length of the longest codeword that is assigned, and to determine the codeword of the final message in the list. The length of the longest codeword is defined as Lₘₐₓ, and the codeword assigned to the final message in the list is defined as Cₘₐₓ. A codeword budget may then be defined as:
b=2^{L}^{ₘₐₓ}−Cₘₐₓ−1

This budget represents the number of additional codewords of length Lₘₐₓ that are available for allocation to messages before Lₘₐₓ must be increased. From FIG. 3 Lₘₐₓ=6 and Cₘₐₓ=111001. The binary number 111001 is equivalent to the decimal number 57. Therefore in FIG. 7:
b=2⁶−57−1=64−57−1=6

A cost cₙ is then calculated for each codeword for message mₙ in the ensemble by:
cₙ=2^{L}^{ₘₐₓ}^{-L}

Where cₙ is the cost of the codeword for message mₙ requiring a length Lₙ in the basic algorithm. This represents the cost in additional codewords to decrease the length of codeword for message mₙ by 1 bit. The list of message probabilities is again traversed to calculate a new set of codeword lengths. The cost cₙ of each codeword is compared to the budget b until a cost is reached where:
cₙ≦b

A new length is then defined for the codeword using the following equation:
L′ₙ=Lₙ−1

The cost of decreasing this codeword length is then subtracted from the budget. If the cost is not less than the budget, the codeword length is unchanged. Either on the same pass or on a subsequent pass through the list a new set of codewords is then generated using the same rules as before, except that the codewords are no longer dependent on the probabilities, but on the new calculated lengths.

The fifth embodiment of FIG. 7 shows identical results to those shown in the fourth embodiment of FIG. 6 using only fixed point arithmetic. If the codeword lengths are adjusted in the same pass as the calculation of the codewords, then no codeword length information needs to be stored for each message, and thus the size of the message table for the method of the fifth embodiment in FIG. 7 does not need to increase.

The theoretical minimum entropy of the example ensemble used to illustrate the embodiments of the present invention, or the average number of bits necessary to encode a message, is 2.48 bits. The entropy of the compressed ensemble using the first embodiment is 2.64 bits. The entropy of the compressed ensemble using the third embodiment is 2.55 bits. The entropy of the compressed ensemble using the fourth embodiment is 2.52 bits. This same sequence, compressed with a Huffman compressor would yield an entropy of 2.70 bits.

One final improvement to the fourth and fifth embodiments is shown as a sixth embodiment in FIG. 8. In FIG. 8 the probabilities used to generate the table are adjusted to further optimize the efficiency of the compressor. A new skewed probability p′ₙ is defined as:
p′ₙ=ƒₛ(pₑₙ)

The functions ƒₛ referred to as a skewing function. The skewing function chosen must satisfy the following condition, where alphabet a contains N distinct messages:

$${\sum }_{n = 0}^{N - 1} {f}_{s} ( {p}_{n} ) = 1$$

This means that the sum of the new probabilities produced by the skewing function must still total 1. The choice of a skewing function could be defined once for a given compressor, or could be changed dynamically based on the characteristics of the source ensemble. FIG. 8 uses an example skewing function:

$${f}_{s} ( {p}_{i} ) = \{ \begin{matrix}i < M & ( 1 - β ) {p}_{i} \\ i \geq M & {p}_{i} + \frac{1}{N - M} {\sum }_{n = 0}^{M - 1} β {p}_{n}\end{matrix} \}$$

In this function N is the number of distinct messages in a. The first M messages have their probabilities reduced by a factor of β. This reduction of probabilities would introduce an error, and the sum of the probabilities would be less than 1. In the above function, this error is then redistributed across the last N-M messages to guarantee a cumulative probability of 1. In the example of the sixth embodiment shown in FIG. 8, an M of 4 and a β of 0.1 are used. The new probabilities are then processed by the fifth embodiment of the present invention. The compressed ensemble length in FIG. 8 is 110 bits which reaches within one bit of the theoretical limit. Huffman compressors only reach this efficiency in certain situations.

Both the basic compressor of the first embodiment and each of the subsequent embodiments produce codewords that always follow a distinct pattern for a given codeword length. The first codeword of length L+1 can also easily be determined from the last codeword of length L. This simplifies decompression significantly.

By knowing the number of codewords of each length and the order of the messages in the list used to generate the codewords, the codewords can easily be reconstructed. The compressed message can be decompressed with only this information. There is no need to actually store the codewords in a codeword to message translation table as is typically done with Huffman compressors and Shannon-Fano compressors. This leads to a smaller translation table.

Also by knowing the number of codewords of each length, it is also a trivial process to find distinct codewords in the compressed sequence. This means that decompression does not involve walking a tree structure or a list of codewords by increasing codeword length, resulting in faster decompression of the compressed sequence.

It will be recognized that the invention as described can be implemented in multiple ways and the present description is not intended to limit the invention to any specific embodiment. Rather, the invention encompasses multiple methods and means to accomplish the purposes of the invention.

What is claimed is:

1. A method comprising:
creating a list of a number of messages representing one or more symbols according to the number of times any one of the messages occurs within an ensemble;
defining predetermined bounds for a number of sets and assigning each of the number of messages to one of the sets, the occurrence of the any one of the messages falling within the bounds of the set to which the one of the messages is assigned; and
assigning one of a number of codewords to each of the number of messages, the codeword for each of the number of messages within a given one of the number of sets is incremented by 1 from a codeword of a previous one of the number of messages within the same set, and further wherein a codeword for a first of the number of messages within a subsequent set is left shifted one or more times from a last codeword of the previous set plus 1.

2. The method of claim 1, wherein the codeword for the first of the number of messages within any of the subsequent sets is not left shifted if the number of remaining codewords is greater than or equal to the number of remaining messages.

3. The method of claim 1, wherein the order of the list is adjusted according to a set of error terms, each one of the error terms relating to one of the number of messages.

4. The method of claim 3, wherein each of the error terms are based on the number of times the previous message occurs within the ensemble and the codeword assigned to the previous message.

5. The method of claim 3, wherein each of the error terms are based on the number of times each of the messages occurs within the ensemble.

6. The method of claim 1, wherein the order of the list is adjusted according to a predefined skewing function.

7. A method comprising:
creating a list of a number of messages according to the number of times any one of the messages occurs within an ensemble;
adjusting an order of the list according to a set of error terms and creating a weight factor for each of the one of the messages wherein the weight factor is defined by the number of times a respective one of the messages occurs, each one of the error terms associated with a respective one of the number of messages;
defining predetermined bounds for a number of sets and assigning each of the number of messages to one of the sets, the occurrence of the any one of the messages falling within the bounds of the set to which the one of the messages is assigned; and
assigning one of a number of codewords to each of the number of messages, the codeword for each of the number of messages within a given one of the number of sets is incremented by 1 from a codeword of a previous one of the number of messages within the same set, and further wherein a codeword for a first of the number of messages within a subsequent set is left shifted one or more times from a last codeword of the previous set plus 1.

8. The method of claim 7, wherein each of the error terms are based on the number of times the previous message occurs within the ensemble and the codeword assigned to the previous message.

9. The method of claim 7, wherein each of the error terms are based on the number of times each of the messages occurs within the ensemble.

10. A method comprising:
creating a list of a number of messages according to the number of times any one of the messages occurs within an ensemble;
adjusting the order of the list according to a predefined skewing function;
defining predetermined bounds for a number of sets and assigning each of the number of messages to one of the sets, the occurrence of the any one of the messages falling within the bounds of the set to which the one of the messages is assigned; and
assigning one of a number of codewords to each of the number of messages, the codeword for each of the number of messages within a given one of the number of sets is incremented by 1 from a codeword of a previous one of the number of messages within the same set, and further wherein a codeword for a first of the number of messages within a subsequent set is left shifted one or more times from a last codeword of the previous set plus 1.
